(19) United States
(12) Patent Application Publication
(10) Pub. No.: US 2021/0134383 A1
(43) Pub. Date: May 6, 2021

(54) MEMORY SYSTEM AND OPERATING METHOD OF THE MEMORY SYSTEM

(71) Applicant: SK hynix Inc., Icheon-si Gyeonggi-do (KR)

(72) Inventor: Jung Sik CHOI, Icheon-si Gyeonggi-do (KR)

(73) Assignee: SK hynix Inc., Icheon-si Gyeonggi-do (KR)

(21) Appl. No.: 16/918,765

(22) Filed: Jul. 1, 2020

(30) Foreign Application Priority Data
Oct. 30, 2019 (KR) 10-2019-0136769

(51) Int. Cl. G11C 29/38; G11C 29/44

(52) U.S. Cl. CPC G11C 29/38; G11C 29/44

(57) ABSTRACT

There are provided a memory system and an operating method of the memory system. The memory system includes: a memory device including a plurality of semiconductor memories; and a controller for controlling the memory device to perform a bad block detection operation on free blocks among a plurality of memory blocks included in a selected semiconductor memory among the plurality of semiconductor memories. The controller selects, as a target memory block, memory blocks adjacent to a bad bock detected based on a result of the bad block detection operation, and controls the memory device to perform the bad block detection operation on the target memory block.

### CROSS-REFERENCE TO RELATED APPLICATION

The present application claims priority under 35 U.S.C. §119(a) to Korean patent application number 10-2019-0136769, filed on Oct. 30, 2019, in the Korean Intellectual Property Office, the entire disclosure of which is incorporated herein by reference

### BACKGROUND

### 1. Technical Field

The present disclosure generally relates to an electronic device, and more particularly, to a memory system and an operating method of the memory system.

### 2. Related Art

The paradigm on recent computer environments have been turned into ubiquitous computing environments in which computing systems can be used anywhere and anytime. This promotes increasing the usage of portable electronic devices such as mobile phones, digital cameras, notebook computers, and the like. Such portable electronic devices may generally include a memory system using a memory device, i.e., a data storage device. The data storage device is used as a main memory device or an auxiliary memory device of the portable electronic devices.

A data storage device using a memory device has excellent stability and durability, high information access speed, and low power consumption, since there is no mechanical driving part. In an example of memory systems having such advantages, the data storage device includes a Universal Serial Bus (USB) memory device, memory cards having various interfaces, a Solid State Drive (SSD), and the like.

The memory device is generally classified into a volatile memory device and a nonvolatile memory device.

The nonvolatile memory device has relatively slow write and read speeds, but retains stored data even when the supply of power is interrupted. Thus, the nonvolatile memory device is used to store data to be retained regardless of whether power is supplied.

Examples of the volatile memory include a Read Only Memory (ROM), a Mask ROM (MROM), a Programmable ROM (PROM), an Electrically Programmable ROM (EPROM), an Electrically Erasable and Programmable ROM (EEPROM), a flash memory, a Phase-change RAM (PRAM), a Magnetic RAM (MRAM), a Resistive RAM (RRAM), a Ferroelectric RAM (FRAM), and the like. The flash memory is classified into a NOR type flash memory and a NAND type flash memory.

### SUMMARY

In accordance with an aspect of the present disclosure, there is provided a memory system which may include: a memory device including a plurality of semiconductor memories; and a controller configured to control the memory device to perform a bad block detection operation on free blocks among a plurality of memory blocks included in a selected semiconductor memory among the plurality of semiconductor memories, wherein the controller selects, as a target memory block, memory blocks adjacent to a bad bock detected based on a result of the bad block detection operation, and controls the memory device to perform the bad block detection operation on the target memory block.

In accordance with another aspect of the present disclosure, there is provided a memory system which may include: a memory device including a first semiconductor memory and a second semiconductor memory, wherein each of the first semiconductor memory and the second semiconductor memory includes a plurality of planes; and a controller configured to control the memory device to perform a bad block detection operation on free blocks among a plurality of memory blocks included in the plurality of planes of the first semiconductor memory, wherein the controller selects, as a target memory block, memory blocks of a plane including a bad block detected as a result of the bad block detection operation, and controls the semiconductor memory to perform the bad block detection operation on the selected target memory block.

In accordance with still another aspect of the present disclosure, there is provided a method for operating a memory system, the method may include: performing a bad block detection operation on a plurality of memory blocks included in a first semiconductor memory; updating, in a bad block table, information on a bad block detected as a result of the bad block detection operation; selecting memory blocks adjacent to the detected bad block as target memory blocks; and performing the bad block detection operation on the target memory blocks.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the examples of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a memory system in accordance with an embodiment of the present disclosure.

FIG. 2 is a block diagram illustrating a configuration of a controller shown in FIG. 1.

FIG. 3 is a block diagram illustrating a bad block manager shown in FIG. 2.

FIG. 4 is a diagram illustrating a semiconductor memory shown in FIG. 1.

FIG. 5 is a diagram illustrating memory blocks included in a memory cell array shown in FIG. 4.

FIG. 6 is a diagram illustrating a memory block shown in FIG. 5.

FIG. 7 is a diagram illustrating an embodiment of a three-dimensionally configured memory block.

FIG. 8 is a flowchart illustrating an operating method of the memory system in accordance with an embodiment of the present disclosure.

FIGS. 9 and 10 are diagrams illustrating an operating method of the memory system in accordance with an embodiment of the present disclosure.

FIG. 11 is a diagram illustrating another embodiment of the memory system.

FIG. 12 is a diagram illustrating another embodiment of the memory system.

FIG. 13 is a diagram illustrating another embodiment of the memory system.

FIG. 14 is a diagram illustrating another embodiment of the memory system.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, embodiments of the present disclosure will be described in detail with reference to the accompanying drawings in order for those skilled in the art to be able to readily implement the technical spirit of the present disclosure.

Embodiments may provide a memory system for performing a bad block detection operation on memory blocks adjacent to a memory block determined as a bad block among memory blocks included in a semiconductor memory, and an operating method of the memory system.

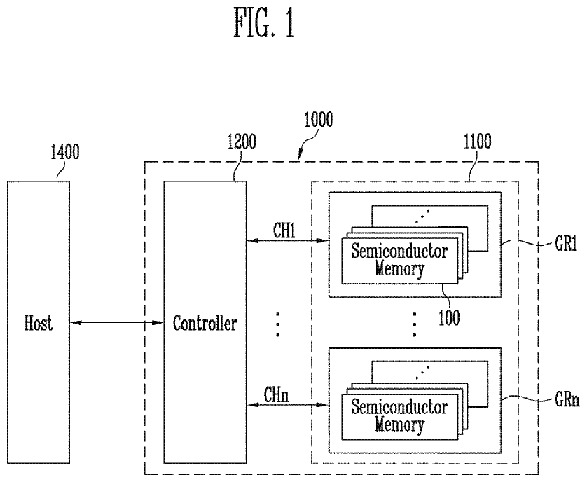

FIG. 1 is a block diagram illustrating a memory system in accordance with an embodiment of the present disclosure.

Referring to FIG. 1, the memory system 1000 includes a memory device 1100 and a controller 1200. The memory device 1100 includes a plurality of semiconductor memories 100. The plurality of semiconductor memories 100 may be divided into a plurality of groups GR1 to GRn.

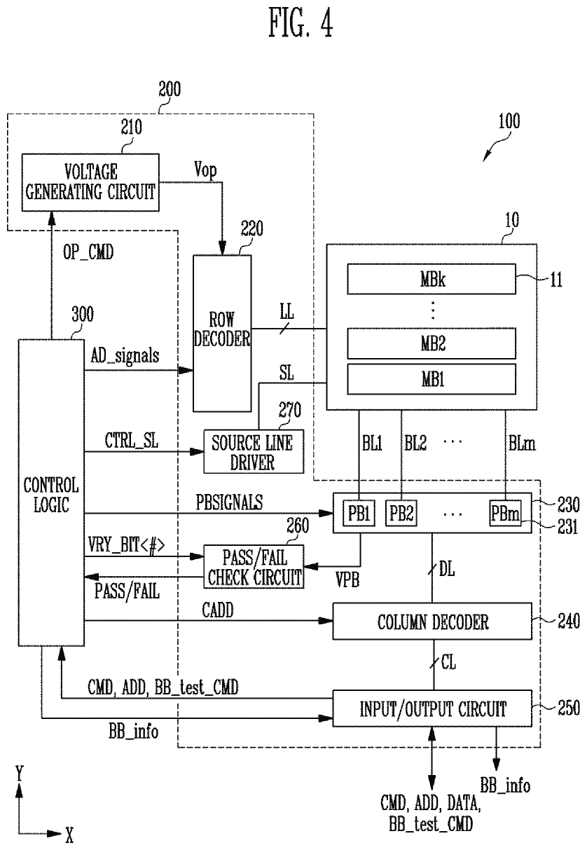

In FIG. 1, a case where the plurality of groups GR1 to GRn communicate with the controller 1200 respectively through first to nth channels CH1 to CHn is illustrated. Each semiconductor memory 100 will be described later with reference to FIG. 4.

Each of the plurality of groups GR1 to GRn communicates with the controller 1200 through one common channel. The controller 1200 controls the plurality of semiconductor memories 100 of the memory device 1100 through the plurality of channels CH to CHn. Each of the semiconductor memories 100 may include a plurality of memory blocks, perform a test operation including a program operation, a read operation, or an erase operation on a selected memory block in a bad block detection operation, and transmit, as bad block information, information on a memory block determined as fail as a result of the test operation to the controller 1200.

The controller 1200 is coupled between a host 1400 and the memory device 1100. The controller 1200 accesses the memory device 1100 in response to a request from the host 1400. For example, the controller 1200 controls read, write, erase, and background operations of the memory device 1100 in response to a request received from the host 1400. The controller 1200 provides an interface between the memory device 1100 and the host 1400. The controller 1200 drives firmware for controlling the memory device 1100.

The controller 1200 may control the memory device 1100 to perform a bad block detection operation on free blocks in an erase state, in which valid data is not stored when the memory device 1100 is in an idle state in which it is waiting without performing any general operation. The controller 1200 may receive bad block information from the memory device 1100, and update a detected bad block in a bad block table. The bad block table may be stored in the memory device 1100, and be read in a power-on operation of the memory system 1000 to be loaded into the controller 1200. The bad block table may include Manufacture Bad Block (MBB) information and Growing Bad Block (GBB) information.

The controller 1200 may select memory blocks adjacent to a bad block detected by the bad block detection operation, and control the memory device 1100 to perform the bad block detection operation on the selected memory blocks.

The host 1400 controls the memory system 1000. The host 1400 includes portable electronic devices such as a computer, a PDA, a PMP, an MP3 player, a camera, a camcorder, and a mobile phone. The host 1400 may request a write operation, a read operation, an erase operation, etc. of the memory system 1000 through a command.

The controller 1200 and the memory device 1100 may be integrated into one semiconductor device. In an embodiment, the controller 1200 and the memory device 1100 may be integrated into one semiconductor device, to constitute a memory card. For example, the controller 1200 and the memory device 1100 may be integrated into one semiconductor device, to constitute a memory card such as a PC card (Personal Computer Memory Card International Association (PCMCIA)), a Compact Flash (CF) card, a Smart Media Card (SM or SMC), a memory stick, a Multi-Media Card (MMC, RS-MMC or MMCmicro), an SD card (SD, miniSD, microSD or SDHC), or a Universal Flash Storage (UFS).

The controller 1200 and the memory device 1100 may be integrated into one semiconductor device to constitute a semiconductor drive (Solid State Drive (SSD)). The semiconductor drive SSD includes a storage device configured to store data in a semiconductor memory. When the memory system 1000 is used as the semiconductor drive (SDD), the operating speed of the host 1400 coupled to the memory system 1000 is remarkably improved.

In another example, the memory system 1000 may be provided as one of various components of an electronic device such as a computer, an Ultra Mobile PC (UMPC), a workstation, a net-book, a Personal Digital Assistant (PDA), a portable computer, a web tablet, a wireless phone, a mobile phone, a smart phone, an e-book, a Portable Multi-Media Player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

In an embodiment, the memory device 1100 or the memory system 1000 may be packaged in various forms. For example, the memory device 1100 or the memory system 1000 may be packaged in a manner such as Package On Package (PoP), Ball Grid Arrays (BGAs), Chip Scale Packages (CSPs), Plastic Leaded Chip Carrier (PLCC), Plastic Dual In-line Package (PDIP), die in Waffle pack, die in wafer form, Chip On Board (COB), CERamic Dual In-line Package (CERDIP), Plastic Metric Quad Flat Pack (PMQFP), Thin Quad Flat Pack (TQFP), Small Outline Integrated Circuit (SOIC), Shrink Small Outline Package (SSOP), Thin Small Outline Package (TSOP), System In Package (SIP), Multi-Chip Package (MCP), Wafer-level Fabricated Package (WFP), or Wafer-level processed Stack Package (WSP).

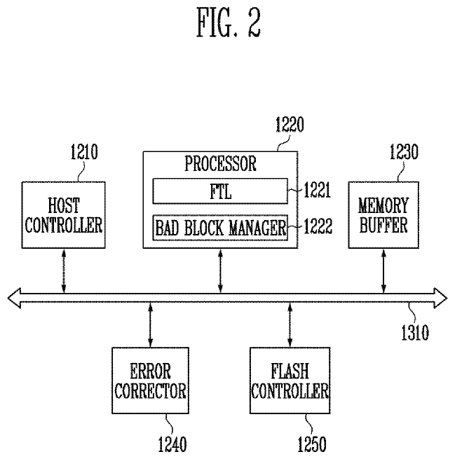

FIG. 2 is a block diagram illustrating a configuration of the controller shown in FIG. 1.

Referring to FIG. 2, the controller 1200 may include a host controller 1210, a processor 1220, a memory buffer 1230, an error corrector 1240, a flash controller 1250, and a bus 1310.

The bus 1310 may provide a channel between components of the controller 1200.

The host controller 1210 may control data transmission between the host 1400 shown in FIG. 1 and the memory buffer 1230. In an example, the host controller 1210 may control an operation of buffering data input from the host 1400 to the memory buffer 1230. In another example, the host controller 1210 may control an operation of outputting, to the host 1400, the data buffered to the memory buffer 1230. The host controller 1210 may include a host interface.

The processor 1220 may control the overall operations of the controller 1200, and perform a logical operation. The processor 1220 may communicate with the host 1400 shown in FIG. 1 through the host controller 1210, and communicate with the memory device 1100 shown in FIG. 1 through the flash controller 1250. For example, when a plurality of host commands (a write command, a read command, an erase command, and the like) are received from the host 1400, the processor 1220 may generate a command queue by queuing the plurality of host commands according to an order of priority.

Also, the processor 1220 may control the memory buffer 1230. The processor 1220 may control an operation of the memory system 1000 by using the memory buffer 1230 as a working memory, a cache memory, or a buffer memory.

The processor 1220 may include a Flash Translation Layer (hereinafter, referred to as ‘FTL’) 1221 and a bad block manager 1222.

The FTL 1221 drives firmware stored in the memory buffer 1230. Also, the FTL 1221 may map a corresponding physical address to a logical address input from the host 1400 shown in FIG. 1 in a data write operation. Also, the FTL 1221 checks the physical address mapped to the logical address input from the host 1400 in a data read operation.

The bad block manager 1222 may load and store a bad block table stored in the memory device (1100 shown in FIG. 1) in a power-on operation of the memory system, and generate a bad block test command for controlling the memory device 1100 to perform a bad block detection operation on free blocks included in the memory device 1100 when the memory device 1100 is in an idle state. The bad block manager 1222 updates, in the bad block table, a newly detected bad block in the bad block detection operation.

Also, the bad block manager 1222 may select memory blocks physically adjacent to the newly detected bad block, memory blocks having block addresses adjacent to that of the newly detected block, or memory blocks sharing word lines with the newly detected block, and generate a bad block test command for controlling the memory device to perform a bad block detection operation on the selected memory blocks. The generated bad block test command may be queued in a command queue, or be transmitted to a selected semiconductor memory 100 of the memory device 1100.

When the selected memory blocks are memory blocks in which valid data is stored in the bad block detection operation on the selected memory blocks, the processor 1220 may control the memory device 1100 to copy data stored in the selected memory blocks and store the copied data in a free block of a semiconductor memory different from that including the selected memory blocks. Also, the processor 1220 may control the memory device 1100 to recover original data of a memory block determined as a normal memory block as a result of the bad block detection operation on the selected memory blocks.

The memory buffer 1230 may be used as a working memory, cache memory or buffer memory of the processor 1220. The memory buffer 1230 may store codes and commands, which are executed by the processor 1220. The memory buffer 1230 may store data processed by the processor 1220. The memory buffer 1230 may include a Static RAM (SRAM) or a Dynamic RAM (DRAM). The memory buffer 1230 may store a command queue generated by the processor 1220.

The memory buffer 1230 may receive and temporarily store valid data from selected memory blocks in a bad block detection operation of the selected memory blocks, and transmit the temporarily stored data to another semiconductor memory. Also, the memory buffer 1230 may receive and temporarily store valid data from another semiconductor memory in an original data recovery operation of a normal memory block on which the bad block detection operation has been completed, and transmit the temporarily stored data to a semiconductor memory including the normal memory block on which the bad block detection operation has been completed.

The error corrector 1240 may perform error correction. The error corrector 1240 may perform Error Correction Code (ECC) encoding, based on data to be written to the memory device 1100 shown in FIG. 1 through the flash controller 1250. The ECC-encoded data may be transferred to the memory device 1100 through the flash controller 1250. The error corrector 1240 may perform ECC decoding on data received from the memory device 1100 through the flash controller 1250. In an example, the error corrector 1240 may be included in the flash controller 1250 as a component of the flash controller 1250.

The flash controller 1250 generates and outputs an internal command for controlling the memory device 1100 in response to a command queue generated by the processor 1220. The flash controller 1250 may control a program operation by transmitting data buffered to the memory buffer 1230 to the memory device 1100 in a data write operation. In another example, the flash controller 1250 may control an operation of buffering data read and output from the memory device 1100 to the memory buffer 1230 in response to the command queue in a read operation. The flash controller 1250 may include a flash interface.

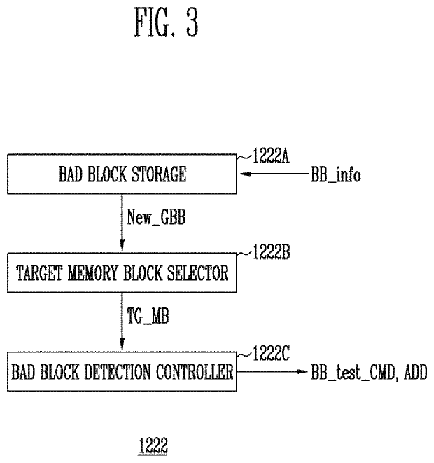

FIG. 3 is a block diagram illustrating the bad block manager shown in FIG. 2.

Referring to FIG. 3, the bad block manager 1222 may include a bad block storage 1222A, a target memory block selector 1222B, and a bad block detection controller 1222C.

The bad block storage 1222A receives and stores a bad block table from the memory device (1100 shown in FIG. 1) in a power-on operation of the memory system. The bad block table may include information on bad blocks included in each of the plurality of semiconductor memories included in the memory device 1100. For example, the bad block table may include addresses of the bad blocks included in each of the plurality of semiconductor memories.

The bad block storage 1222A may manage the bad block table by updating information on a new bad block in the bad block table, based on bad block information BB_info received from the plurality of semiconductor memories included in the memory device 1100.

The bad block storage 1222A may output information New_GBB on a newly updated bad block. The information New_GBB on the newly updated bad block may include a block address of a newly updated GBB.

When the memory device 1100 is in an idle state, the target memory block selector 1222B may select a target memory block on which a bad block detection operation is to be performed among free blocks included in the plurality of semiconductor memories included in the memory device 1100, and output target memory block information TG_MB including information on the selected target memory block. The target memory block information TG_MB may include a block address of the selected target memory block.

The target memory block selector 1222B may select a target memory block on which a bad block detection operation is to be performed, based on the information New_GBB on the newly updated bad block, which is received from the bad block storage 1222A. For example, the target memory block selector 1222B may select, as the target memory block, memory blocks physically adjacent to the newly updated bad block, memory blocks having block addresses adjacent to that of the newly updated bad block, or memory blocks sharing word lines with the newly updated bad block, based on the information New_GBB on the newly updated bad block.

The bad block detection controller 1222C generates and outputs a bad block test command BB_test_CMD and an address ADD, which are used to control the memory device 1100 to perform a bad block detection operation, based on the target memory block information TG_MB received from the target memory block selector 1222B.

FIG. 4 is a diagram illustrating the semiconductor memory shown in FIG. 1.

Referring to FIG. 4, the semiconductor memory 100 may include a memory cell array 10 which stores data. The semiconductor memory 100 may include a peripheral circuit 200 configured to perform a program operation for storing data in the memory cell array 10, a read operation for outputting the stored data, and an erase operation for erasing the stored data. The semiconductor memory 100 may include control logic 300 which controls the peripheral circuit 200 under the control of the controller (1200 shown in FIG. 1). The control logic 300 may be implemented as hardware, software, or a combination of hardware and software. For example, the control logic 300 may be a control logic circuit operating in accordance with an algorithm and/or a processor executing control logic code.

The memory cell array 10 may include a plurality of memory blocks MB1 to MBk 11 (k is a positive integer). At least one memory block among the plurality of memory blocks MB1 to MBk may be a CAM block, and the CAM block may store a bad block table. Local lines LL and bit lines BL1 to BLm (m is a positive integer) may be coupled to the memory blocks MB1 to MBk 11. For example, the local lines LL may include a first select line, a second select line, and a plurality of word lines arranged between the first and second select lines. Also, the local lines LL may include dummy lines arranged between the first select line and the word lines and between the second select line and the word lines. The first select line may be a source select line, and the second select line may be a drain select line. For example, the local lines LL may include word lines, drain and source select lines, and source lines SL. For example, the local lines LL may further include dummy lines. For example, the local lines LL may further include pipe lines. The local lines LL may be coupled to the memory blocks MB1 to MBk 11, respectively, and the bit lines BL1 to BLm may be commonly coupled to the memory blocks MB1 to MBk 11. The memory blocks MB1 to MBk 11 may be implemented in a two-dimensional or three-dimensional structure. For example, memory cells may be arranged in a direction parallel to a substrate in memory blocks 11 having a two-dimensional structure. For example, memory cells may be arranged in a direction vertical to a substrate in memory blocks 11 having a three-dimensional structure.

The peripheral circuit 200 may be configured to perform program, read, and erase operations of a selected memory block 11 under the control of the control logic 300. For example, the peripheral circuit 200 may include a voltage generating circuit 210, a row decoder 220, a page buffer group 230, a column decoder 240, an input/output circuit 250, a pass/fail check circuit 260, and a source line driver 270.

The voltage generating circuit 210 may generate various operating voltages Vop used for program, read, and erase operations in response to an operation signal OP_CMD. Also, the voltage generating circuit 210 may selectively discharge the local lines LL in response to the operation signal OP_CMD. For example, the voltage generating circuit 210 may generate a program voltage, a verify voltage, a pass voltage, and a select transistor operation voltage under the control of the control logic 300.

The row decoder 220 may transfer the operating voltages Vop to local lines LL coupled to the selected memory block 11 in response to row decoder control signals AD_signals. For example, the row decoder 220 may selectively apply operation voltages (e.g., a program voltage, a verify voltage, a read voltage, a pass voltage, and the like) generated by the voltage generating circuit 210 to word lines among the local lines LL in response to the row decoder control signals AD_signals.

For example, in a program voltage applying operation, the row decoder 220 applies a program voltage generated by the voltage generating circuit 210 to a selected word line among the local lines LL in the row decoder control signals AD_signals, and applies a pass voltage generated by the voltage generating circuit 210 to the other unselected word lines. Also, in a read operation, the row decoder 220 applies a read voltage generated by the voltage generating circuit 210 to a selected word line among the logical lines LL in response to the row decoder control signals AD_signals, and applies a pass voltage generated by the voltage generating circuit 210 to the other unselected word lines.

The page buffer group 230 may include a plurality of page buffers PB1 to PBm 231 coupled to the bit lines BL1 to BLm. The page buffers PB1 to PBm 231 may operate in response to page buffer control signals PBSIGNALS. For example, the page buffers PB1 to PBm 231 may temporarily store data to be programmed in a program operation, or sense voltages or currents of the bit lines BL1 to BLm in a read or verify operation.

The column decoder 240 may transfer data between the input/output circuit 250 and the page buffer group 230 in response to a column address CADD. For example, the column decoder 240 may exchange data with the page buffers 231 through data lines DL, or exchange data with the input/output circuit 250 through column lines CL.

The input/output circuit 250 may transfer an internal command CMD, a bad block test command BB_test_CMD, and an address ADD, which are received from the controller (1200 shown in FIG. 1), to the control logic 300, or receive bad block information BB_info from the control logic 300 and then transfer to received bad block information BB_info to the controller 1200. Also, the input/output circuit 250 may exchange data DATA with the column decoder 240.

In a read operation or verify operation, the pass/fail check circuit 260 may generate a reference current in response to an allow bit VRY_BIT<#>, and output a pass signal PASS or a fail signal FAIL by comparing a sensing voltage VPB received from the page buffer group 230 with a reference voltage generated by the reference current. Also, in a bad block test operation, the pass/fail check circuit 260 may output a pass signal PASS or a fail signal FAIL by comparing a sensing voltage VPB received from the page buffer group 230 with a reference voltage generated by the reference current.

The source line driver 270 may be coupled to a memory cell included in the memory cell array 10 through a source line SL, and control a voltage applied to the source line SL. The source line driver 270 may receive a source line control signal CTRL_SL from the control logic 300, and control a source line voltage (e.g., an erase voltage) applied to the source line SL, based on the source line control signal CTRL_SL.

The control logic 300 may control the peripheral circuit 200 to perform a general operation, e.g., a program operation, a read operation, an erase operation, or the like by outputting the operation signal OP_CMD, the row decoder control signals AD_signals, the page buffer control signals PBSIGNALS, and the allow bit VRY_BIT<#>in response to the internal command CMD and the address ADD. Also, the control logic 300 may determine whether the program operation, the read operation, or the erase operation has been passed or failed in response to the pass or fail signal PASS or FAIL. Also, the control logic 300 may control the peripheral circuit 200 to perform a bad block detection operation on a target memory block in response to the bad block test command BB_test_CMD and the address ADD. For example, the bad block detection operation may include a test program operation on at least one selected page among a plurality of pages included in the target memory block, a test read operation on a page on which the test program operation has been completed, or a test erase operation on the target memory block. In the test program operation, the test read operation, or the test erase operation, the control logic 300 may determine whether the target memory block is a GBB or a normal memory block, based on the pass signal PAA or the fail signal FAIL, which is received from the pass/fail check circuit 260, and generate and output bad block information BB_info, based on the determination result.

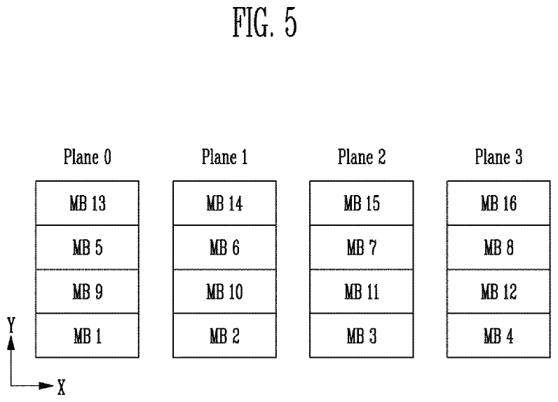

FIG. 5 is a diagram illustrating memory blocks included in the memory cell array shown in FIG. 4. The number of memory blocks and planes are not limited to what is shown in the figures and can be more or less than what is shown and described.

Referring to FIG. 5, a plurality of memory blocks MB1 to MB16 may be arranged in a matrix form. The plurality of memory blocks MB1 to MB16 may be divided into one or more planes Plane 0 to Plane 3.

For example, a plurality of memory blocks MB1, MB5, MB9, and MB13 may be included in a plane Plane 0, a plurality of memory blocks MB2, MB6, MB10, and MB14 may be included in a plane Plane 1, a plurality of memory blocks MB3, MB7, MB 11, and MB15 may be included in a plane Plane 2, and a plurality of memory blocks MB4, MB8, MB12, and MB16 may be included in a plane Plane 3.

A plurality of memory blocks included in the same plane are memory blocks adjacent in a Y direction. For example, the plurality of memory blocks MB1, MB5, MB9, and MB13 included in the plane Plane 0 may be memory blocks adjacent in the Y direction, the plurality of memory blocks MB2, MB6, MB10, and MB14 included in the plane Plane 1 may be memory blocks adjacent in the Y direction, the plurality of memory blocks MB3, MB7, MB 11, and MB15 included in the plane Plane 2 may be memory blocks adjacent in the Y direction, and the plurality of memory blocks MB4, MB8, MB12, and MB16 included in the plane Plane 3 may be memory blocks adjacent in the Y direction.

In addition, a plurality of memory blocks included in each plane may be adjacent to memory blocks included in different planes in an X direction. For example, the memory blocks MB1 to MB4 are memory blocks which are included in different planes and are adjacent to each other in the X direction, the memory blocks MB5 to MB8 are memory blocks which are included in different planes and are adjacent to each other in the X direction, the memory blocks MB9 to MB12 are memory blocks which are included in different planes and are adjacent to each other in the X direction, and the memory blocks MB13 to MB16 are memory blocks which are included in different planes and are adjacent to each other in the X direction.

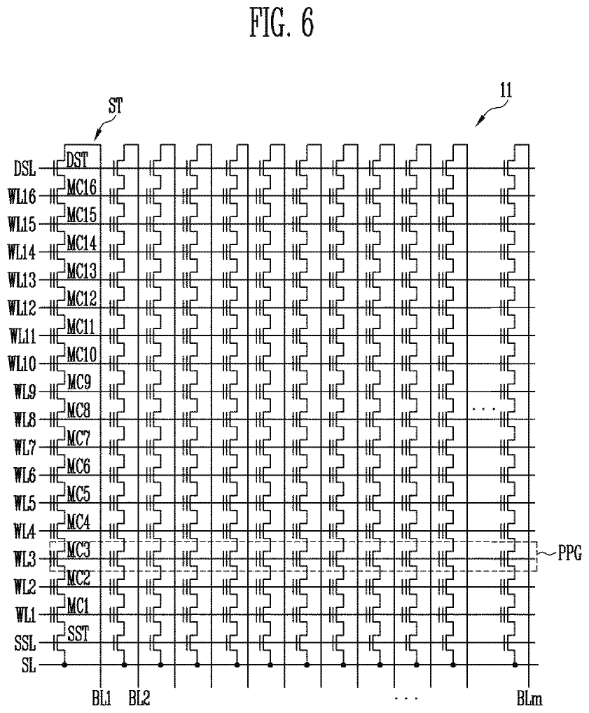

FIG. 6 is a diagram illustrating a memory block shown in FIG. 5.

Referring to FIG. 6, in the memory block11, a plurality of word lines WL1 to WL16 arranged in parallel to one another may be coupled between a first select line and a second select line. The first select line may be a source select line SSL, and the second select line may be a drain select line DSL. For example, the memory block 11 may include a plurality of strings ST coupled between bit lines BL1 to BLm and a source line SL. The bit lines BL1 to BLm may be coupled to the strings ST, respectively, and the source line SL may be commonly coupled to the strings ST. The strings ST may be configured identically to one another, and therefore, a string ST coupled to a first bit line BL1 will be described as an example.

The string ST may include a source select transistor SST, a plurality of memory cells MC1 to MC16, and a drain select transistor DST, which are coupled in series between the source line SL and the first bit line BL1. At least one source select transistor SST and at least one drain select transistor DST may be included in one string ST, and memory cells of which number is greater than that of the memory cells MC1 to MC16 shown in the drawing may be included in the one string ST.

A source of the source select transistor SST may be coupled to the source line SL, and a drain of the drain select transistor DST may be coupled to the first bit line BL1. The memory cells MC1 to MC16 may be coupled in series between the source select transistor SST and the drain select transistor DST. Gates of source select transistors SST included in different strings ST may be coupled to the source select line SSL, gates of drain select transistors DST included in different strings ST may be coupled to the drain select line DSL, and gates of the memory cells MC1 to MC16 included in different strings ST may be coupled to the plurality of word lines WL1 to WL16. A group of memory cells coupled to the same word line among the memory cells included in different strings ST may be referred as a physical page PPG. Therefore, physical pages PPG of which number corresponds to that of the word lines WL1 to WL16 may be included in the memory block 11.

One memory cell may store data of one bit. The memory cell is generally referred to as a single level cell (SLC). Therefore, one physical page PPG may store one logical page (LPG) data. One LPG data may include data bits corresponding to a number of cells included in one physical page PPG. In addition, one memory cell may store data of two or more bits. The memory cell is generally referred to as a multi-level cell (MLC). Therefore, one physical page PPG may store two or more LPG data.

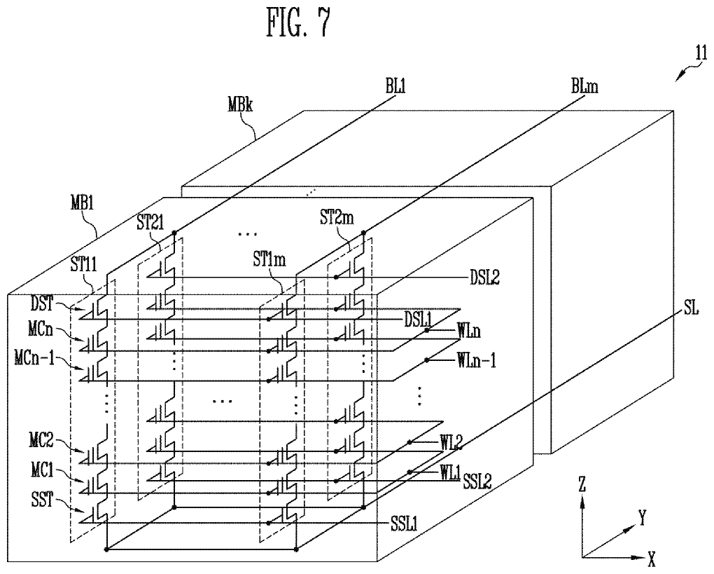

FIG. 7 is a diagram illustrating an embodiment of a three-dimensionally configured memory block.

Referring to FIG. 7, the memory cell array 10 may include a plurality of memory blocks MB1 to MBk 11. Each of the memory blocs from the memory blocks 11 may include a plurality of strings ST11 to ST1m and ST21 to ST2m. Each of the plurality of strings ST11 to ST1m and ST21 to ST2m may extend along a vertical direction (Z direction). In each of the memory blocks 11, m strings may be arranged in a row direction (X direction). Although a case where two strings are arranged in a column direction (Y direction) is illustrated in FIG. 7, this is for convenience of description, and three or more strings may be arranged in the column direction (Y direction).

Each of the plurality of strings ST11 to ST1m and ST21 to ST2m may include at least one source select transistor SST, first to nth memory cells MC1 to MCn, and at least one drain select transistor DST.

The source select transistor SST of each string may be coupled between a source line SL and the memory cells MC1 to MCn. Source select transistors of strings arranged on the same row may be coupled to the same source select line. Source select transistors of strings ST11 to ST1m arranged on a first row may be coupled to a first source select line SSL1. Source select transistors of strings ST21 to ST2m arranged on a second row may be coupled to a second source select line SSL2. In another embodiment, the source select transistors of the strings ST11 to ST1m and ST21 to ST2m may be commonly coupled to one source select line.

The first to nth memory cells MC1 to MCn of each string may be coupled in series to each other between the source select transistor SST and the drain select transistor DST. Gates of the first to nth memory cells MC1 to MCn may be coupled to first to nth word lines WL1 to WLn, respectively.

In an embodiment, at least one of the first to nth memory cells MC1 to MCn may be used as a dummy memory cell. When the dummy memory cell is provided, a voltage or current of a corresponding string can be stably controlled. Accordingly, the reliability of data stored in the memory blocks 11 can be improved.

The drain select transistor DST of each string may be coupled between a bit line and the memory cells MC1 to MCn. Drain select transistors DST of strings arranged in the row direction may be coupled to a drain select line extending in the row direction. Drain select transistors DST of the strings ST11 to ST1m arranged on the first row may be coupled to a first drain select line DSL1. Drain select transistors DST of the strings ST21 to ST2m arranged on the second row may be coupled to a second drain select line DSL2.

In the plurality of memory blocks MB1 to MBk 11, one memory block may share the word lines WL1 to WLn with another memory block, and the memory blocks sharing the word lines WL1 and WLn may be defined as a shared memory block.

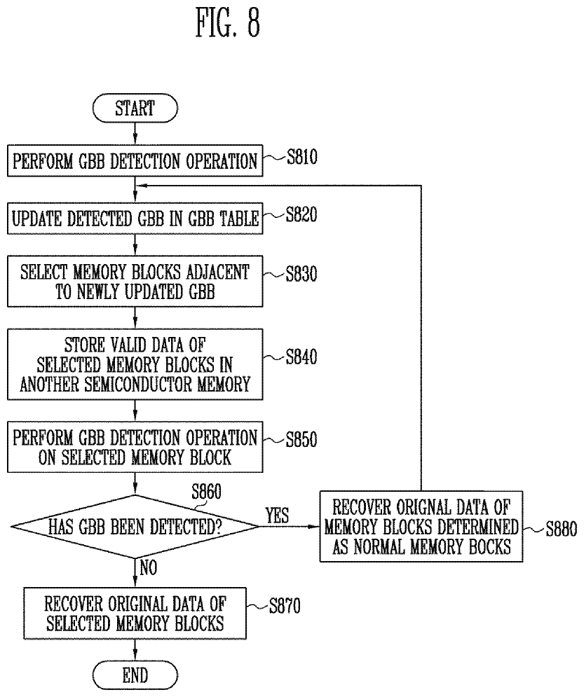

FIG. 8 is a flowchart illustrating an operating method of the memory system in accordance with an embodiment of the present disclosure.

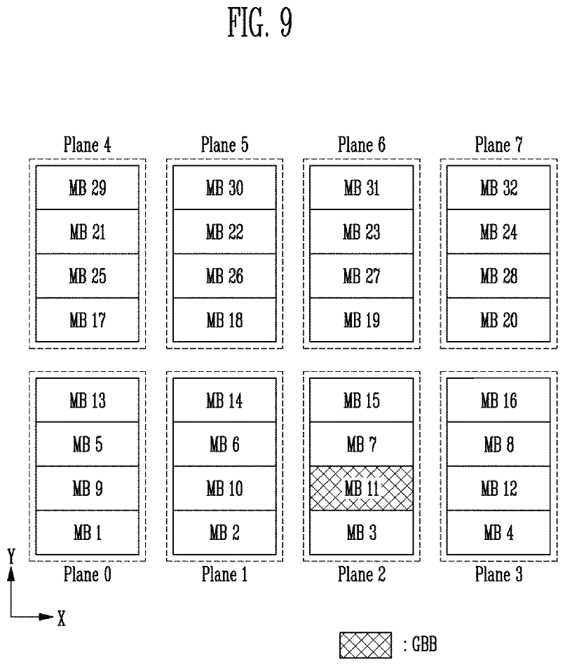

FIGS. 9 and 10 are diagrams illustrating an operating method of the memory system in accordance with an embodiment of the present disclosure.

An operating method of the memory system in accordance with an embodiment of the present disclosure will be described as follows with reference to FIGS. 1 to 10.

In the embodiment of the present disclosure, a case where a plurality of memory blocks MB1 to MB32 are divided into a plurality of planes Plane 0 to Plane 7 as shown in FIGS. 9 and 10 is described as an example.

The controller 1200 selects a semiconductor memory in an idle state among the plurality of semiconductor memories 100 included in the memory device 1100, and generates a bad block test command BB_test_CMD for controlling a bad block detection operation on memory blocks as a free block among a plurality of memory blocks MB1 to MBk included in the selected semiconductor memory and an address ADD corresponding to the memory blocks as the free block and then transmits the bad block test command BB_test_CMD and the address ADD to the selected semiconductor memory.

The selected semiconductor memory 100 receives the bad block test command BB_test_CMD and the address ADD corresponding to the memory blocks as the free block from the controller 1200, and performs a bad block detection operation by sequentially selecting the memory blocks as the free block or by simultaneously selecting at least two memory blocks (S810).

For example, in the bad block detection operation, the selected semiconductor memory 100 selects at least one page among a plurality of pages included in a target memory block (e.g., MB 11) among the memory blocks as the free block, and performs a test program operation on the at least one selected page, a test read operation on a page on which the test program operation has been completed, or a test erase operation on the target memory block. The pass/fail check circuit 260 of the semiconductor memory 100 generates and outputs a pass signal PASS or a fail signal FAIL, based on a result of the test program operation, a result of the test read operation, or a result of the test erase operation, and the control logic 300 generates and outputs bad block information BB_info by determining whether the target memory block MNB11 is a GBB or a normal memory block, based on the pass signal PASS or the fail signal FAIL. The semiconductor memory 100 transmits the bad block information BB_info generated in the bad block detection operation to the controller 1200. In an embodiment of the present disclosure, a case where the memory block MB 11 included in the plane 2 is detected as a bad block GBB as a result of the bad block detection operation is described as an example.

The controller 1200 receives the bad block information BB_info from the selected semiconductor memory 100, and the bad block storage 1222A of the bad block manger 1222 updates, in a bad block GBB table, the memory block MB 11 detected as the bad block GBB in the bad block detection operation, based on the received bad block information BB_info (S820).

The bad block storage 1222A outputs information New_GBB on the newly updated bad block MB 11. The target memory block selector 1222B selects a target memory block on which the bad block detection operation is to be performed, based on the information New_GBB on the newly updated bad block. For example, the target memory block selector 1222B selects, as the target memory block, memory blocks physically adjacent to the newly updated bad block or memory blocks having block addresses adjacent to that of the newly updated bad block, based on the information New_GBB on the newly updated bad block (S830). For example, when the newly updated bad block GBB is the memory block MB 11 as shown in FIG. 10, the target memory block selector 1222B may select, as the target memory block, the memory blocks MB 3, MB 7, and MB 15 which are included in the same plane Plane as the memory block MB 11 and are adjacent in a Y direction, and the memory blocks MB 9, MB 10, and MB 12 which are included in different planes Plane 0, Plane 1, and Plane 3 and are adjacent in an X direction. In addition, when a memory block having a block address adjacent that of the memory block MB 11 is selected as the target memory block, the target memory block selector 1222B may select, as the target memory block, a memory block having a block address higher by a set number than that of the memory block MB 11 and a memory block having a block address lower by the set number than that of the memory block MB 11. In an embodiment of the present disclosure, when the set number is 8, the memory block MB 19 and the memory block MB 3 may be set as the target memory block. In some embodiments, memory blocks having block addresses adjacent to those of the memory blocks physically adjacent to that of the newly updated bad block may be selected together with the memory blocks MB19 and MB3 as the target memory block.

The processor 1220 controls the memory device 1100 to copy data stored in a memory block in which valid data is stored among the selected memory blocks (e.g., MB 3, MB 7, MB 9, MB 10, MB 12, MB 15, and MB 19) and store the data in memory blocks of a semiconductor memory different from that including the selected memory blocks MB 3, MB 7, MB 9, MB 10, MB 12, MB 15, and MB 19 (S840).

For example, when valid data is stored in the memory blocks MB 3 and MB 7 among the selected memory blocks MB 3, MB 7, MB 9, MB 10, MB 12, MB 15, and MB 19, the semiconductor memory reads the valid data stored in the memory blocks MB 3 and MB 7 and transmits the read valid data to the memory buffer 1230 of the controller 1200. Subsequently, an erase operation may be performed on the memory blocks MB 3 and MB 7. The processor 1220 selects a new semiconductor memory and then transmits the valid data stored in the memory buffer 1230 to the new semiconductor memory, and the new semiconductor memory programs the received valid data to free blocks.

The controller 1200 generates a bad block test command BB_test_CMD for controlling the bad block detection operation on the selected memory blocks MB 3, MB 7, MB 9, MB 10, MB 12, MB 15, and MB 19 and an address ADD corresponding to the selected memory blocks MB 3, MB 7, MB 9, MB 10, MB 12, MB 15, and MB 19, and transmits the bad block test command BB_test_CMD and the address ADD to the selected semiconductor memory.

The selected semiconductor memory 100 receives the bad block test command BB_test_CMD and the address ADD from the controller 1200, and performs the bad block detection operation by sequentially selecting the selected memory blocks MB 3, MB 7, MB 9, MB 10, MB 12, MB 15, and MB 19 or by simultaneously selecting at least two memory blocks (S850).

The processor 1220 determines whether a bad block has been detected, based on bad block information BB_info received in the bad block detection operation on the selected memory blocks MB 3, MB 7, MB 9, MB 10, MB 12, MB 15, and MB 19 (S860).

As a result of the step S860 of determining whether a bad block has been detected, when the selected memory blocks MB 3, MB 7, MB 9, MB 10, MB 12, MB 15, and MB 19 are all determined as normal memory blocks (No), the processor 1220 recovers original data of the memory blocks MB 3 and MB 7 by transmitting original data of the selected memory blocks MB 3, MB 7, MB 9, MB 10, MB 12, MB 15, and MB 19 to another semiconductor memory (S870).

For example, the processor 1220 controls the memory device 1100 to read valid data stored in another semiconductor memory in the step S840 and transmit the read valid data to the memory buffer 1230. The processor 1220 controls the memory device 1100 to transmit the valid data stored in the memory buffer 1230 to the semiconductor memory including the memory blocks MB 3 and MB 7 and program the transmitted valid data to the memory blocks MB 3 and MB 7.

As a result of the step S860 of determining whether a bad block has been detected, when at least one memory block among the selected memory blocks MB 3, MB 7, MB 9, MB 10, MB 12, MB 15, and MB 19 is determined as a bad block GBB (Yes), the processor 1220 recovers the original data of the memory blocks MB 3 and MB 7 by transmitting, to another semiconductor memory, original data of memory blocks determined as normal memory blocks among the selected memory blocks MB 3, MB 7, MB 9, MB 10, MB 12, MB 15, and MB 19. A method for recovering original data is similar to the above-described step S870, and therefore, its detailed description will be omitted.

Subsequently, the bad block manager 1222 of the processor 1220 re-performs the above-described steps from the step S820 of updating the detected bad block GBB in the bad block table, based on the bad block information BB info.

As described above, in accordance with the embodiments of the present disclosure, when a bad block is detected as a result of a bad block detection operation, the bad block detection operation is performed on memory blocks physically adjacent to the detected bad block or memory blocks having block addresses adjacent to that of the detected bad block. Accordingly, memory blocks having a high probability that they will be bad blocks are determined as the bad blocks in advance, so that the reliability of the memory system can be improved.

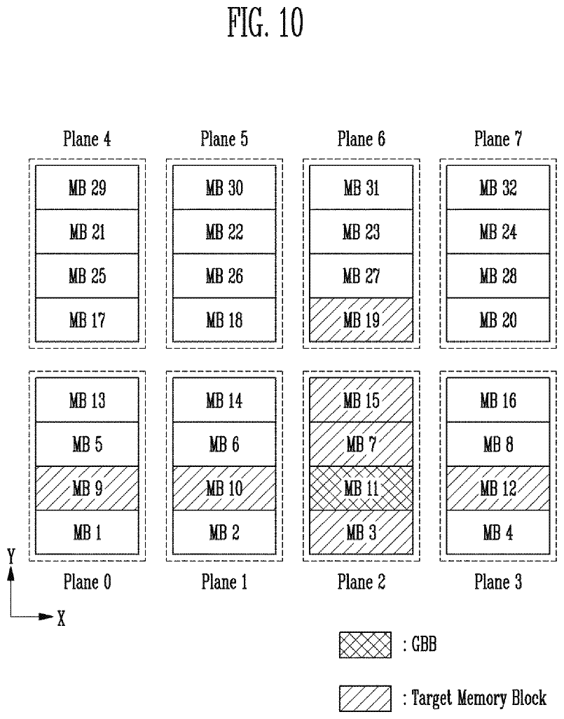

FIG. 11 is a diagram illustrating another embodiment of the memory system.

Referring to FIG. 11, the memory system 30000 may be implemented as a cellular phone, a smart phone, a tablet PC, a personal digital assistant (PDA), or a wireless communication device. The memory system 30000 may include a memory device 1100 and a controller 1200 capable of controlling an operation of the memory device 1100. The controller 1200 may control a data access operation of the memory device 1100, e.g., a program operation, an erase operation, a read operation, or the like under the control of a processor 3100.

Data programmed in the memory device 1100 may be output through a display 3200 under the control of the controller 1200.

A radio transceiver 3300 may transmit/receive radio signals through an antenna ANT. For example, the radio transceiver 3300 may change a radio signal received through the antenna ANT into a signal that can be processed by the processor 3100. Therefore, the processor 3100 may process a signal output from the radio transceiver 3300 and transmit the processed signal to the controller 1200 or the display 3200. The controller 1200 may transmit the signal processed by the processor 3100 to the memory device 1100. Also, the radio transceiver 3300 may change a signal output from the processor 3100 into a radio signal, and output the changed radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mount, a keypad, or a keyboard. The processor 3100 may control an operation of the display 3200 such that data output from the controller 1200, data output from the radio transceiver 3300, or data output from the input device 3400 can be output through the display 3200.

In some embodiments, the controller 1200 capable of controlling an operation of the memory device 1100 may be implemented as a part of the processor 3100, or be implemented as a chip separate from the processor 3100. Also, the controller 1200 may be implemented with the controller shown in FIG. 2.

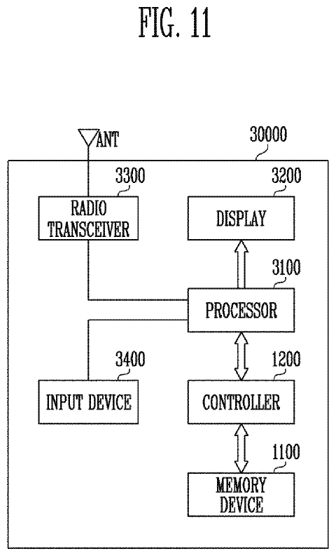

FIG. 12 is a diagram illustrating another embodiment of the memory system.

Referring to FIG. 12, the memory system 40000 may be implemented as a personal computer (PC), a tablet PC, a net-book, an e-reader, a personal digital assistant (PDA), a portable multi-media player (PMP), an MP3 player, or an MP4 player.

The memory system 40000 may include a memory device 1100 and a controller 1200 capable of controlling a data processing operation of the memory device 1100.

A processor 4100 may output data stored in the memory device 1100 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the controller 1200. In some embodiments, the controller 1200 capable of controlling an operation of the memory device 1100 may be implemented as a part of the processor 4100, or be implemented as a chip separate from the processor 4100. Also, the controller 1200 may be implemented with the controller shown in FIG. 2.

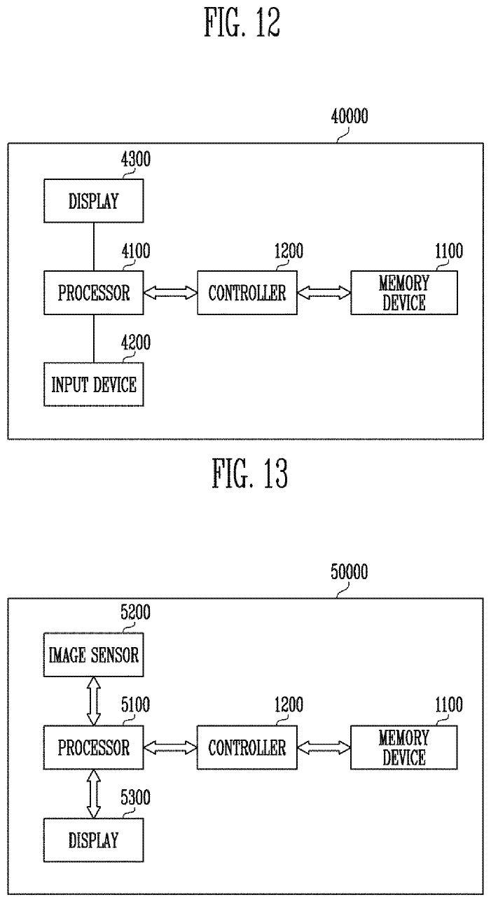

FIG. 13 is a diagram illustrating another embodiment of the memory system.

Referring to FIG. 13, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 1100 and a controller 1200 capable of controlling a data processing operation of the memory device 1100, e.g., a program operation, an erase operation, or a read operation.

An image sensor 5200 of the memory system 50000 may convert an optical image into digital signals, and the converted digital signals may be transmitted to a processor 5100 or the controller 1200. Under the control of the processor 5100, the converted digital signals may be output through a display 5300, or be stored in the memory device 1100 through the controller 1200. In addition, data stored in the memory device 1100 may be output through the display 5300 under the control of the processor 5100 or the controller 1200.

In some embodiments, the controller 1200 capable of controlling an operation of the memory device 1100 may be implemented as a part of the processor 5100, or be implemented as a chip separate from the processor 5100. Also, the controller 1200 may be implemented with the controller shown in FIG. 2.

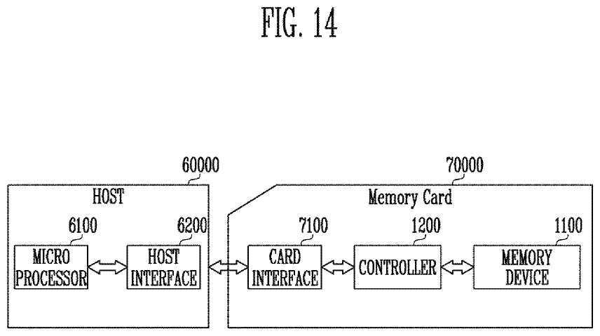

FIG. 14 is a diagram illustrating another embodiment of the memory system.

Referring to FIG. 14, the memory system 70000 may be implemented as a memory card or a smart card. The memory system 70000 may include a memory device 1100, a controller 1200, and a card interface 7100.

The controller 1200 may control data exchange between the memory device 1100 and the card interface 7100. In some embodiments, the card interface 7100 may be a secure digital (SD) card interface or a multi-media card (MMC) interface, but the present disclosure is not limited thereto. Also, the controller 1200 may be implemented with the controller shown in FIG. 2.

The card interface 7100 may interface data exchange between a host 60000 and the controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is coupled to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the controller 1200 under the control of a microprocessor 6100.

In accordance with the present disclosure, a bad block detection operation is performed on memory blocks adjacent to a memory block determined as a bad block among memory blocks included in a semiconductor memory, so that the reliability of the memory system can be improved.

While the present disclosure has been shown and described with reference to certain examples of embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory system comprising:
a memory device including a plurality of semiconductor memories; and
a controller configured to control the memory device to perform a bad block detection operation on free blocks among a plurality of memory blocks included in a selected semiconductor memory among the plurality of semiconductor memories,
wherein the controller selects, as a target memory block, memory blocks adjacent to a bad block detected based on a result of the bad block detection operation, and controls the memory device to perform the bad block detection operation on the target memory block.

2. The memory system of claim 1, wherein the plurality of memory blocks are divided into a plurality of planes, and first memory blocks included in each plane are adjacent to each other in a first direction.

3. The memory system of claim 2, wherein the first memory blocks included in each plane are adjacent to second memory blocks included in a plane different from the plane in a second direction.

4. The memory system of claim 3, wherein the controller selects, as the target memory block, the first memory blocks included in the same plane as the detected bad block or the controller selects, as the target memory block, the second memory blocks included in a plane different from that of the detected bad block.

5. The memory system of claim 1, wherein the controller selects, as the target memory block, memory blocks having block addresses adjacent to that of the detected bad block.

6. The memory system of claim 1, wherein the controller controls the memory device to store in another semiconductor memory, except the selected semiconductor memory among the plurality of semiconductor memories, by reading valid data stored in the target memory block.

7. The memory system of claim 6, wherein, when the target memory block is determined as a normal memory block as a result of the bad bock detection operation on the target memory block, the controller reads the valid data stored in the another semiconductor memory and stores the read valid data in the target memory block.

8. The memory system of claim 6, wherein, when the target memory block is determined as a bad block as a result of the bad block detection operation on the target memory block, the controller controls the memory device to perform the bad block detection operation by selecting memory blocks adjacent to the target memory block as the target memory block.

9. A memory system comprising:
a memory device including a first semiconductor memory and a second semiconductor memory, wherein each of the first semiconductor memory and the second semiconductor memory includes a plurality of planes; and
a controller configured to control the memory device to perform a bad block detection operation on free blocks among a plurality of memory blocks included in the plurality of planes of the first semiconductor memory,
wherein the controller selects, as a target memory block, memory blocks of a plane including a bad block detected as a result of the bad block detection operation, and controls the semiconductor memory to perform the bad block detection operation on the selected target memory block.

10. The memory system of claim 9, wherein memory blocks of each of the plurality of planes are adjacent to each other in a first direction,
wherein the controller selects, as the target memory block, the memory blocks of the plane including the detected bad block.

11. The memory system of claim 9, wherein the controller selects, as the target memory block, memory blocks which are included in a plane different from that including the detected bad block and are adjacent to the detected bad block in a second direction.

12. The memory system of claim 9, wherein the controller includes:
a bad block storage configured to update a bad block table by receiving bad block information from the memory device, and output newly updated bad block information;
a target memory block selector configured to select the target memory block, based on the newly updated bad block information; and
a bad block detection controller configured to generate and output a bad block test command corresponding to the bad block detection operation on the target memory block.

13. The memory system of claim 12, wherein the first semiconductor memory generates the bad block information by performing the bad block detection operation on the target memory block in response to the bad block test command, and transmits the generated bad block information to the controller.

14. The memory system of claim 13, wherein the first semiconductor memory performs at least one of a test program operation, a test read operation, and a test erase operation on the target memory block in the bad block detection operation.

15. The memory system of claim 9, wherein the controller controls the memory device to read valid data stored in the target memory block and store the read valid data in the second semiconductor memory,
wherein, when the target memory block is determined as a normal memory block as a result of the bad block detection operation on the target memory block, the controller controls the memory device to read the valid data stored in the second semiconductor memory and store the read valid data in the target memory block.

16. A method for operating a memory system, the method comprising:
performing a bad block detection operation on a plurality of memory blocks included in a first semiconductor memory;
updating, in a bad block table, information on a bad block detected as a result of the bad block detection operation;
selecting memory blocks adjacent to the detected bad block as target memory blocks; and
performing the bad block detection operation on the target memory blocks.

17. The method of claim 16, wherein the memory blocks adjacent to the bad block are included in the same plane as the bad block.

18. The method of claim 16, wherein the memory blocks adjacent to the bad block have block addresses adjacent to that of the bad block.

19. The method of claim 16, further comprising reading valid data stored in the target memory block and storing the read valid data in the second semiconductor memory, before the performing of the bad block detection operation on the target memory blocks.

20. The method of claim 19, further comprising reading the valid data stored in the second semiconductor memory with respect to memory blocks determined as normal memory blocks among the target memory blocks as a result of the bad block detection operation and storing the read valid data in the memory blocks determined as the normal memory blocks.
